(19) United States
(12) Patent Application Publication
(10) Pub. No.: US 2019/0304705 A1
(43) Pub. Date: Oct. 3, 2019

(54) COMPOSITE PEROVSKITE MATERIALS, METHODS OF MAKING, AND METHODS OF USE

(71) Applicant: King Abdullah University of Science and Technology, Thuwal (SA)

(72) Inventors: Weili YU, Thuwal (SA); Aram AMASSIAN, Thuwal (SA)

(73) Assignee: King Abdullah University of Science and Technology, Thuwal (SA)

(21) Appl. No.: 16/307,585

(22) PCT Filed: Jun. 5, 2017
(86) PCT No.: PCT/IB2017/053313

§ 371 Date: Dec. 6, 2018

Related U.S. Application Data
(60) Provisional application No. 62/346,610, filed on Jun. 7, 2016.

(51) Int. Cl. H01G 9/20; H01L 51/42; H01L 51/00

(52) U.S. Cl. CPC H01G 9/2009; H01L 51/0077; H01L 51/0049; H01L 51/4253

(57) ABSTRACT

Embodiments of the present disclosure provide materials, devices and systems including a composite of halide perovskite single crystals and nanotubes, and the like. Embodiments of the composite can be used in devices such as detectors, solar panels, transistors, sensors, and the like.

### CROSS-REFERENCE TO RELATED APPLICATIONS

This application claims the benefit of and priority to U.S. Provisional Application Ser. No. 62/346,610, having the title “COMPOSITE PEROVSKITE MATERIALS, METHODS OF MAKING, AND METHODS OF USE”, filed on Jun. 7, 2016, the disclosure of which is incorporated herein in by reference in its entirety.

### BACKGROUND

Due to their large light absorption coefficient, tunable absorption, and solution processability, organolead halide perovskite materials have attracted a great deal of attention. Compared with their polycrystalline film counterparts, perovskite single crystals (SCs) possess several merits such as high carrier mobility, long carrier diffusion length and low trap-state densities. How to make full use of the merits into real performances is still a great challenge.

### SUMMARY

Embodiments of the present disclosure provide compositions and methods of making a composite perovskite nanocrystal nanotube materials and the like.

An embodiment of the present disclosure includes a composite of halide perovskite single crystals and nanotubes, wherein a type I heterojunction is formed between halide perovskite single crystal and nanotubes.

An embodiment of the present disclosure also includes a photodetector device comprising halide perovskite single crystals and nanotubes, wherein a type I heterojunction is formed between halide perovskite single crystal and nanotubes.

An embodiment of the present disclosure also includes a solar cell comprising halide perovskite single crystals and nanotubes, wherein a type I heterojunction is formed between halide perovskite single crystal and nanotubes.

Other compositions, devices, methods, features, and advantages will be or become apparent to one with skill in the art upon examination of the following drawings and detailed description. It is intended that all such additional compositions, devices, methods, features and advantages be included within this description, be within the scope of the present disclosure, and be protected by the accompanying claims.

### BRIEF DESCRIPTION OF THE DRAWINGS

Further aspects of the present disclosure will be more readily appreciated upon review of the detailed description of its various embodiments, described below, when taken in conjunction with the accompanying drawings.

FIGS. 1A-G illustrate MAPbBr₃/SWNTs SCC characterization. FIG. 1A illustrates the energy-level alignment between perovskite and SVWNTs. FIG. 1B illustrates the proposed structure of MAPbBr₃/SVWNTs SCC (Blue, methylammonium; black, lead; red, bromide). Photo-generated holes are injected into the SWNTs, while electrons are mainly transported by the perovskite. FIG. 1C illustrates the digital photographs of the MAPbBr₃/SWNTs SCC and MAPbBr₃ SC. Left: MAPbBr₃/SWNTS SCC; right: MAPbBr₃ SC. FIG. 1D illustrates the scanning electron microscopy image of the MAPbBr₃/SWNTs SCC. Scale bar, 250 nm. FIG. 1E illustrates the Raman spectra of MAPbBr₃ SC and MAPbBr₃/SWNTs SCC. Excitation wavelength is 633 nm. FIG. 1F illustrate the UV-Vis absorption spectra of MAPbBr₃ SC, SWNTs and MAPbBr₃/SWNTs SCC, respectively. FIG. 1G illustrates the SAED of MAPbBr₃/SWNTs SCC.

FIGS. 2A-D demonstrate photoluminescence, transient absorption measurements and I-Vtraces. FIG. 2A illustrates the photoluminescence spectrum of MAPbBr₃ SC and MAPbBr₃/SWNTs SCC upon excitation at 532 nm. FIG. 2B illustrates the dynamics spectra of MAPbBr₃ SC and MAPbBr₃/SWNTs SCC. FIG. 2C-D illustrates the characteristic I-V trace (purple markers) showing three different regimes for MAPbBr₃ SCs and MAPbBr₃/SWNTs SCC. The regions are marked for Ohmic (Magenta line), Child (Orange line) and TFL's regime (Navy line).

FIGS. 3A-E show a schematic of and graphs of performance of photodetectors. FIG. 3A illustrate the schematic layout of the photodetector structure. FIG. 3B illustrate the typical I-V curves of photodetector based on MAPbBr₃/SWNTs SCC at the sweeping bias voltages from −2 V to 2 V. FIG. 3C illustrates the photocurrent density and photo-responsivity versus light power density of the hybrid photodetector measured at −2 V and illumination wavelength of 500 nm. FIG. 3D illustrates the typical I-V curves of the pristine photodetector at the sweeping bias voltages from −2 V to 2 V. FIG. 3E illustrates the photocurrent density and photo-responsivity versus light power density of the pristine photodetector measured at −2 V and illumination wavelength of 500 nm.

FIGS. 4A-E demonstrate device performance. FIG. 4A illustrates the responsivities for the photodetectors based on MAPbBr₃/SWNTs SCC and MAPbBr₃ single crystal, respectively. FIG. 4B illustrates the noise current of the photodetector based on MAPbBr₃SWNTs SCC. Inset shows the noise current of MAPbBr₃-based device. FIG. 4C illustrates the detectivities for the photodetectors based on MAPbBr₃/SWNTs SCC and MAPbBr₃ single crystal, respectively. FIG. 4D illustrate the temporal Photocurrent responsive characteristic of the hybrid perovskite/SWNTs photodetector. FIG. 4E illustrate the temporal photocurrent response, indicating a rise time of 0.91 ms and a decay time of 1.43 ms.

FIGS. 5A-B illustrate (FIG. 5A) TEM and (FIG. 5B) SEM images of SWNTs used to fabricate the perovskite/SWNTs single crystals-like composite. The diameter of SWNT is about 1 nm.

FIG. 6 illustrates an SEM image of cross-section of MAPbBr₃/SWNT single crystals-like composite. The SWNTs are closely surrounded by the perovskite bulks, and one of them was outstretched, which might have resulted when we cut the single crystals-like composite. This SEM image provides the direct evidence that SWNTs were successfully implanted into MAPbBr₃ SC. The planted SWNTs were closely connected with (or surrounded by) the MAPbBr₃ SC, which will help to collect the photogenerated carriers and to extract them out to the surface, where electrode exits.

FIG. 7 illustrates an SEM image of the surface of pure MAPbBr₃ SC.

FIG. 8 shows the powder XRD pattern of MAPbBr₃ crystal and MAPbBr₃/SWNTs SCC. The XRD data indicate that introducing SWNTs into the matrix did not change the cubic crystal structure of MAPbBr₃ SCs, and thus the photonic and electronic properties of MAPbBr₃ perovskites were expected to be well maintained.

FIGS. 9A-B are HRTEM images (FIG. 9A) and SAED pattern (FIG. 9B) of MAPbBr SCs.

FIGS. 10A-B show transient absorption spectra of (FIG. 10A) MAPbBr₃ SC and (FIG. 10B) MAPbBr₃/SWNTs SCC, respectively. From the results obtained from dynamic spectra and biexponential data fitting, we retrieved the time constants for both materials, which relate to the charge transfer from perovskites to SWNTs.

FIGS. 11A-B illustrate the response time of the MAPbBr₃-based photodetector. FIG. 11A illustrates the temporal photocurrent responsive characteristic of the MAPbBr₃ photodetector with a time interval of 1.0 s. FIG. 11B illustrates the temporal photocurrent response, indicating a rise time of 4.85 ms and a decay time of 7.36 ms.

### DETAILED DESCRIPTION

Before the present disclosure is described in greater detail, it is to be understood that this disclosure is not limited to particular embodiments described, as such may, of course, vary. It is also to be understood that the terminology used herein is for the purpose of describing particular embodiments only, and is not intended to be limiting, since the scope of the present disclosure will be limited only by the appended claims.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. Where the stated range includes one or both of the limits, ranges excluding either or both of those included limits are also included in the disclosure.

Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, the preferred methods and materials are now described.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure. Any recited method can be carried out in the order of events recited or in any other order that is logically possible.

Embodiments of the present disclosure will employ, unless otherwise indicated, techniques of chemistry, material science, synthetic organic chemistry, and the like, which are within the skill of the art. Such techniques are explained fully in the literature.

The following examples are put forth so as to provide those of ordinary skill in the art with a complete disclosure and description of how to perform the methods and use the compositions and compounds disclosed and claimed herein. Efforts have been made to ensure accuracy with respect to numbers (e.g., amounts, temperature, etc.), but some errors and deviations should be accounted for. Unless indicated otherwise, parts are parts by weight, temperature is in ° C., and pressure is in bar. Standard temperature and pressure are defined as 25° C. and 1 bar.

Before the embodiments of the present disclosure are described in detail, it is to be understood that, unless otherwise indicated, the present disclosure is not limited to particular materials, reagents, reaction materials, manufacturing processes, or the like, as such can vary. It is also to be understood that the terminology used herein is for purposes of describing particular embodiments only, and is not intended to be limiting. It is also possible in the present disclosure that steps can be executed in different sequence where this is logically possible.

It must be noted that, as used in the specification and the appended claims, the singular forms “a,” “an,” and “the” include plural referents unless the context clearly dictates otherwise. Thus, for example, reference to “a support” includes a plurality of supports. In this specification and in the claims that follow, reference will be made to a number of terms that shall be defined to have the following meanings unless a contrary intention is apparent.

### GENERAL DISCUSSION

Embodiments of the present disclosure provide materials, devices and systems including a composite of halide perovskite single crystals and nanotubes, and the like.

In an aspect the composite can be used in devices such as detectors, solar panels, transistors, sensors, and the like. In an embodiment, the composite can be used in a NIR photodetector and can have a wide application range, including environmental monitoring, remote sensing, and medical imaging modalities. In the regard, the devices can have broad appeal as a room-temperature operated broadband photodetector.

Embodiments of the present disclosure provide for the ability to solution-grow organohalide perovskite single crystals in a nanotube (e.g., SWNT) network, resulting in a single crystal-like composite. The energetically favorable interfacial electronic structures lead to charge transfer to the nanotubes capable of moving charges orders of magnitude faster than a pure perovskite matrix. In this regard, the organohalide perovskite single crystals sensitizes the nanotube network, while the latter extends the absorption spectrum of the composite well into to the NIR.

In an aspect, composites of the present disclosure incorporate energetically tuned nanomaterials that can provide a mechanism and pathway for rapid charge transport without preventing the single crystal matrix formation to mitigate the need for ultrathin single crystals.

In an embodiment, a type I heterojunction is formed between MAPbBr₃ and nanotubes (e.g., SWNTs). In an embodiment, the highest occupied molecular orbital (HOMO) of the nanotube can be selected to align closely with the valence band maximum (VBM) of the perovskite (−5.5 eV), once contacting and illumination, charge transfer occurs. The nanotube can become n-type and induce band bending that facilitates efficient hole extraction from the perovskite VBM into the HOMO of nanotube. Photo-excited holes transfer from perovskites to nanotubes, greatly reducing the charge recombination and extending the photodetection spectral range when the macroscopic perovskite crystals can be grown through and around a dense nanotube network with good interfacial contact between the perovskite matrix and the nanotube inclusion.

In an aspect the composite can be used in high-performance photodetectors with a broad spectral response of about 400 nm to 1100 nm, with responsivities about 3895 A W⁻¹ and about 614 A W⁻¹ or more, while also having detectivities of about 3.8×10¹³ Jones and about 5.2×10¹² Jones or more in the visible and NIR regions, respectively. In an embodiment, the composite shows a high gain of about 1.1×10⁵ electrons per photon and the carrier mobility goes up to 967 cm² V⁻¹ s⁻¹. In this regard, devices including these composite can provide device performance metrics that are state of the art and compare favorably to the best organic and inorganic materials used in photodetectors.

Now having described embodiments of the present disclosure generally, additional details are provided below. In an embodiment, the composite can include a halide perovskite and a nanotube, where the halide perovskite is grown in a plurality of nanotubes to form a composite matrix of the halide perovskite crystals around and mixed throughout the plurality of nanotubes. In an embodiment, the composite includes the halide perovskite and the nanotube at a weight ratio of about 1000:1 to 10:1.

In an embodiment, the material can include a halide perovskite having the formula AMX₃ and/or a phosphor. In an embodiment, the halide perovskite can have the following formula: AMX₃. In an embodiment, A can be a monovalent cation such as alkyl-ammonium (e.g., methylammonium (MA)), formamidinium (FA), 5-ammoniumvaleric acid, or an inorganic cation such Cesium (Cs), or a combination thereof. In an embodiment, M can be a cation or divalent cation of an element such as Pb, Sn, Cu, Ni, Co, Fe, Mn, Pd, Cd, Ge, Cs, or Eu. In a particular embodiment, M is Pb. In an embodiment, X can be a halide anion such as Cl, Br, F, and I. In an embodiment, each X can be the same, while in another embodiment, each X can be independently selected from a halide anion. In particular, X is I or Br or Cl. The selection of the components of AMX₃ is made so that the halide perovskite has a neutral charge. In an embodiment, alkyl can refer to linear or branched hydrocarbon moieties having one to six carbon atoms (e.g., methyl, ethyl, propyl, and the like).

In an embodiment, AMX₃ can be: methylammonium lead iodide (MAPbI₃), methylammonium lead bromide (MAPbBr₃), formamidinium lead bromide (FAPbBr₃), formamidinium lead iodide (FAPbI₃), MAPbCl₃, MAPbBr₂Cl, FAPbCl₃, CsPbI₃, CsPbCl₃, CsPbBr₃, FASnBr₃, FASnBr₃, and FASnBr₃, MASnBr₃, MASnBr₃, and MASnBr₃.

In an embodiment, the halide perovskite can be a nanocrystal having a diameter (or longest dimension) of about 3 to 20 nm, about 5 to 10 nm, about 7 to 9 nm, or about 8 nm.

In an embodiment, it may be desirable to have halide perovskite nanocrystals in the range of 2 to 100 nm, and the halide perovskite nanocrystals can be fabricated according to the desired use or function.

In an embodiment, the halide perovskite can be nanocrystals and can form microcrystalline film on a substrate, for example a substrate including the nanotubes. In an embodiment, the halide perovskite can be a single crystal halide perovskite, microcrystalline halide perovskites or a polycrystalline halide perovskite.

In an embodiment, the nanotube network can include surface modification by refluxing in HNO₃ to improve the compatibility and stability of SWNTs in perovskite precursor solutions. The modified SWNTs were then introduced into perovskite precursor solution to incubate perovskite-SWNTs composite.

In an embodiment, the nanotube can be made of materials such as, but not limited to, carbon nanotubes, carbon dots, graphene and combinations thereof. The nanotubes have a length of about 0.5 to 1000 nm, a diameter of about 2 to 10 nm, and a thickness of about 1 atom layer. One or more of the dimensions of the nanotubes can potentially be adjusted to provide desirable characteristics. In an embodiment, the nanotubes may be interconnected, isolated or include a mixture of interconnect and isolated nanotubes.

In an embodiment, the nanotube can be a carbon nanotube. In an embodiment, the carbon nanotubes are generally described as large elongated fullerenes of closed-cage carbon molecules typically arranged in hexagons and pentagons. In an embodiment, the carbon nanotubes can be single wall nanotubes (SWNT) or multi-walled nanotubes (MWNT). Embodiments of the MWNT can include 2 or more walls, 5 or more walls, 10 or more walls, 20 or more walls, or 40 or more walls. In an embodiment, the carbon nanotubes including SWNTs and MWNTs may have diameters from about 0.6 nanometers (nm) up to about 3 nm, about 5 nm, about 10 nm, about 30 nm, about 60 nm or about 100 nm. In an embodiment, the single-wall carbon nanotubes may have a length from about 50 nm up to about 1 micro-meter (μm), or greater. In an embodiment, the diameter of the single-wall carbon nanotube can be about 0.7 to 5 nm and has a length of about 50 to 500 nm.

In an embodiment, the composite can have a thickness of about 1 to 1000 microns and about 100 to 10000 microns. In an embodiment, the length and width can be on the micron scale to cm scale or larger, and can be designed based on the particular use.

In an embodiment, the composite can be formed on a substrate. In an embodiment, the substrate can include glass, Si, indium tin oxide glass, and fluorine doped tin oxide glass, or a combination thereof.

An embodiment of the present disclosure includes a method of making composite of the nanotubes and the halide perovskite. The method includes forming the nanotube network and then forming the halide perovskite crystals around and within the nanotube network to form a composite matrix. Methods of forming nanotubes such as carbon single wall nanotubes are well known. Additional embodiments regarding forming the composite are described in the Example.

In general, the method of forming the halide perovskite includes dissolving MX₂ and AX in a solvent to form dissolved APbX₃ in a container at or near room temperature, where this can be performed on a substrate that includes the nanotube network. The substrate and the solution are in a container so that the material can form on the substrate. In an embodiment, the solubility can be enhanced using a vortex mixer. In an embodiment, undissolved MX₂ or AX can be filtered out. In an embodiment, A can be an organic cation.

In an embodiment, the concentration of the MX₂ can be about 4 to 44 weight %. In an embodiment, the concentration of the AX can be about 2 to 15 weight %.

In an embodiment, M can be selected from: Pb cation. Sn cation, Cu cation, Ni cation, Co cation, Fe cation, Mn cation, Pd cation, Cd cation, Ge cation, or Eu cation, Cs cation, and in a particular embodiment, M can be Pb²I. In an embodiment, X can be a halide such as Br⁻, Cl⁻, or I⁻. In an embodiment, A is a cation selected from methylammonium, formamidinium, and Cesium (Cs).

In an embodiment, the solvent can be N,N-dimethylformamide (DMF), dimethylsulfoxide (DMSO), gamma-butyrolactone (GBL), dichlorobenzene (DCB), toluene, or a combination thereof, depending upon the AMX₃ structure to be formed.

Subsequently, the mixture in the solvent is heated to a temperature (e.g., about 40 to 150° C.) so that the microcrystalline film (e.g., APbX₃ structure) forms, where the temperature corresponds to the inverse temperature solubility for dissolved microcrystalline film (e.g., APbX₃). In an embodiment, the APbX₃ structure can be formed in about 0.5-3 h.

In an embodiment, the solvent is matched with the reactants so that at room temperature the reactants are soluble in the solvent, but at higher temperatures, the APbX₃ structure is formed (e.g., crystallizes). In this regard, when a MAPbBr₃ perovskite structure is to be formed, the solvent used is N,N-dimethylformamide (DMF). In another embodiment, when a MAPbI₃ perovskite structure is to be formed, the solvent is γ-butyrolactone (GBL). In another embodiment, when a MAPbCl₃ perovskite structure is to be formed, the solvent is dimethylsulfoxide (DMSO) and DMF (1:1 ratio).

In a particular embodiment, MAPbBr₃ perovskite single crystals are grown through a dense SWNT network and form a solution-grown macroscopic single crystals-like composite exhibiting dramatically enhanced mobility (˜1000 cm²Ns for the composite) and optoelectronic properties. The perovskite acts as a visible light-sensitizer while the SWNTs extend the broadband light response from below 550 nm (for MAPbBr₃ SC only) to 1100 nm. We characterized photodetection figures of merits of the composite and found its responsivity (R) and D* to increase by more than two orders of magnitude as compared with pure perovskite single crystals, even in the visible, where the perovskite performs the best. For the MAPbBr₃/SWNTs composite, R over 3895 A W⁻¹ and 614 A W⁻¹, together with D* exceeding 3.8×10¹³ Jones and 5.2×10¹² Jones were observed in the visible and NIR regions, respectively.

### EXAMPLES

Now having described the embodiments of the disclosure, in general, the examples describe some additional embodiments. While embodiments of the present disclosure are described in connection with the example and the corresponding text and figures, there is no intent to limit embodiments of the disclosure to these descriptions. On the contrary, the intent is to cover all alternatives, modifications, and equivalents included within the spirit and scope of embodiments of the present disclosure.

### Example 1

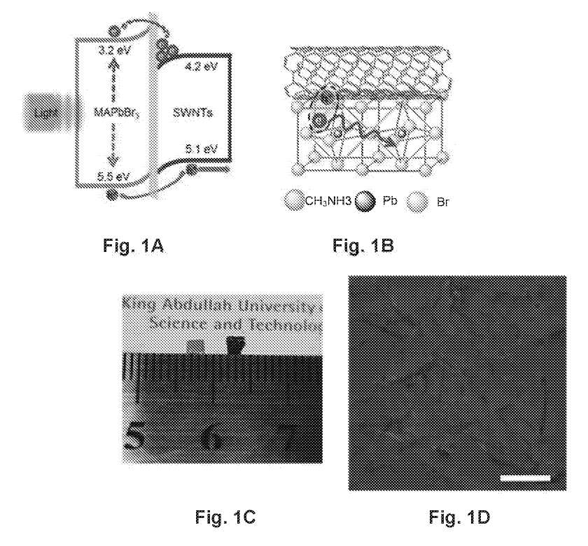

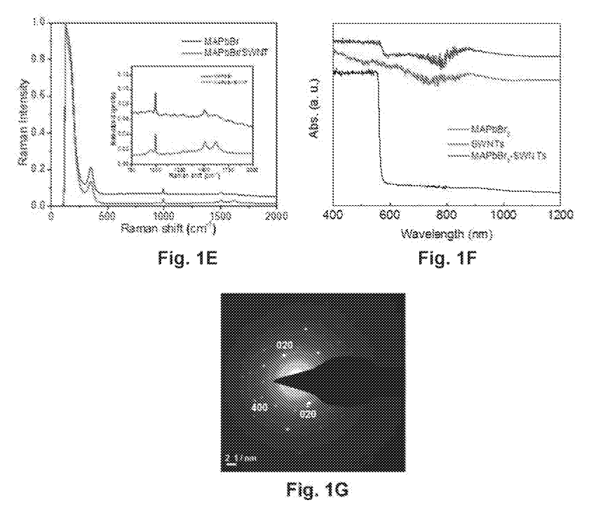

Due to their large light absorption coefficient, tunable absorption, and solution processability, organolead halide perovskite materials ABX₃ (A=CH₃NH₃; B=Pb, X=Br or I) have attracted a great deal of attention in recent years¹⁻⁷, and have triggered tremendous progress in a variety of fields⁸⁻¹². Compared with their polycrystalline film counterparts, perovskite single crystals (SCs) further possess several merits such as high carrier mobility, long carrier diffusion length and low trap-state densities, which make them more promising optoelectronic materials^{13, 14}. How to make full use of the merits into real performances is still a great challenge. For example, SCs based photodetectors have achieved some significant results, like narrowband response (full-width<20 nm at half-maximum peak) and tunable photodetection from blue (425 nm) to red (640 nm)¹⁰. However, the performance of perovskite SC-based photodetectors has been comparatively underwhelming, with reported detectivity (D*)˜10¹⁰ Jones^{10, 15} even lower than that of polycrystalline perovskite thin film devices^{9, 12, 13}. The main culprit for this is believed to be the macroscopically large thickness of perovskite SCs, which sacrifices its high absorption coefficient and causes more recombination losses^{16, 17}. Developing novel techniques to grow perovskite SCs with reduced thickness would be beneficial^{17, 18}, but this remains a significant challenge^{19, 20}. Instead, we took the view that incorporation of energetically tuned nanomaterials which can provide a mechanism and pathway for rapid charge transport without preventing the single crystal matrix formation might mitigate the need for ultrathin single crystals²¹. We hypothesize a type I heterojunction can form between MAPbBr₃ and single wall carbon nanotubes (SWNTs) with a (7,6) chirality, as shown in FIG. 1A. As the highest occupied molecular orbital (HOMO) of SWNTs (−5.1 eV) aligns closely with the valence band maximum (VBM) of the perovskite (−5.5 eV)^{22, 23}, once contacting and illumination, charge transfer is expected to occur between the methylamine compound and SWNTs, as demonstrated by Schultz et al.²³ The SWNTs thus become n-type and induce band bending which may facilitate efficient hole extraction from the perovskite VBM into the HOMO of SWNTs. Photo-excited holes should thus transfer from perovskites to SWNTs, greatly reducing the charge recombination and extending the photodetection spectral range on condition that macroscopic perovskite SCs can be grown through and around a dense SWNT network with good interfacial contact between the perovskite matrix and the SWNT inclusion.

Here, we show the remarkable ability of MAPbBr₃ perovskite SCs to grow through a dense SWNT network and form a solution-grown macroscopic single crystals-like composite (SCC, FIG. 1B) exhibiting dramatically enhanced mobility (˜1000 cm²Ns for the composite) and optoelectronic properties. The perovskite acts as a visible light-sensitizer while the SWNTs extend the broadband light response from below 550 nm (for MAPbBr₃ SC only)¹³ to 1100 nm. We characterized photodetection figures of merits of the SCC and found its responsivity (R) and D* to increase by more than two orders of magnitude as compared with pure perovskite SCs, even in the visible, where the perovskite performs the best. For the MAPbBr₃/SWNTs SCC, R over 3895 A W⁻¹ and 614 A W⁻¹, together with D* exceeding 3.8×10¹³ Jones and 5.2×10¹² Jones were observed in the visible and NIR regions, respectively. As NIR photodetectors have a wide application range, including environmental monitoring, remote sensing, medical imaging modalities,²⁴⁻²⁶ the MAPbBr₃/SWNT SCC has a potentially broad appeal as a room-temperature operated broadband photodetector. This work demonstrates that perovskites are amenable to forming SCCs with nanomaterials, which can provide entirely new routes to enhancing or tuning the performance of the matrix and inclusion while maintaining the single crystal matrix material intact.

### Results

### Single Crystals-Like Composite (SCC) of Perovskite/SWNTs.

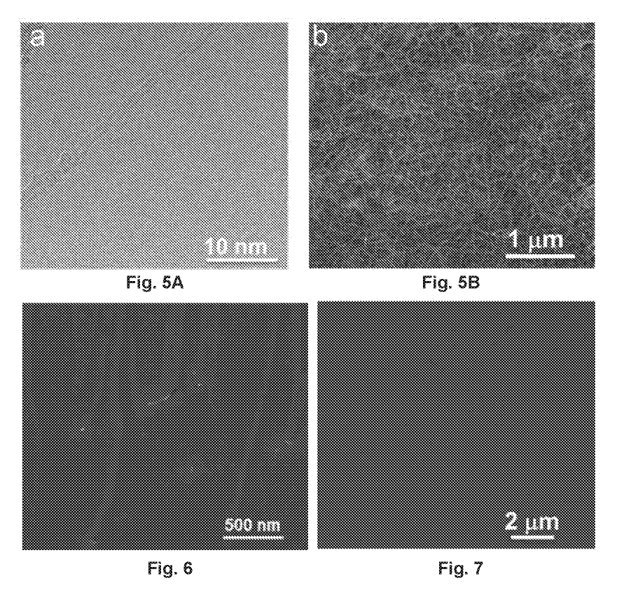

We first process the commercial SWNTs by refluxing them in HNO₃ to improve the compatibility and stability of SWNTs in perovskite precursor solutions. The SWNTs were characterized by transmission electron microscopy (TEM) and scanning electron microscopy (SEM). As shown in FIGS. 5A-B, the SWNTs are 0.5-2 μm in length and 0.9±0.2 nm in diameter. The SEMs of neat SWNTs revealed significant entanglements between the nanotubes, which indicate the nanotubes will most likely be interconnected inside the composite crystal as well. Subsequently, a high-quality MAPbBr₃/SWNTs composite was prepared following a reported strategy of perovskite SC growth¹³. Previous studies have claimed that the crystallization process of perovskites is governed by both thermodynamic and kinetic factors^{27, 28}. In this case, although the exact mechanism of MAPbBr₃ SC nucleation and growth in the presence of SWNTs is not fully understood, we found that the perovskite crystallization process was thermodynamically favored in the presence of SWNTs²⁷, and the surface modification of SWNTs was also necessary in this regard²⁹. Using the anti-solvent vapor-assisted crystallization technique¹³, we have grown pure and composite single crystals, as featured in the digital photograph (FIG. 1C). The pure MAPbBr₃ SC is transparent orange, in agreement with previous reports¹³, whereas the composite crystal is much darker, with a black color.

SEM images of the surface (FIG. 1D) and the cross-section of composite crystals (FIG. 6) reveal the presence of SWNTs closely surrounded by perovskite material throughout the crystal, contrast to the pure perovskite surface (FIG. 7). Raman spectra of MAPbBr₃ SC and MAPbBr₃/SWNTs SCC are shown in FIG. 1E, the sharp peak at 1620 cm⁻¹ can be assigned to the G-mode region of SWNTs³⁰, confirming the inclusion of SWNTs in MAPbBr₃ SC. The UV-Vis absorption spectra of MAPbBr₃/SWNTs SCC and pure perovskite SC are shown in FIG. 1F, from which one can see that the pure MAPbBr₃ SC shows an absorption cutoff at 550 nm, corresponding to a bandgap of 2.25 eV. The sharp absorption edge cutoff proves that the MAPbBr₃ SC structure is similar to those reported previously^{13, 14.} The absorption spectra of MAPbBr₃/SWNTs SCC extends to 1100 nm, and the absorption above 550 nm is closely consistent with the absorption of SWNTs, especially for wavelength above 800 nm.

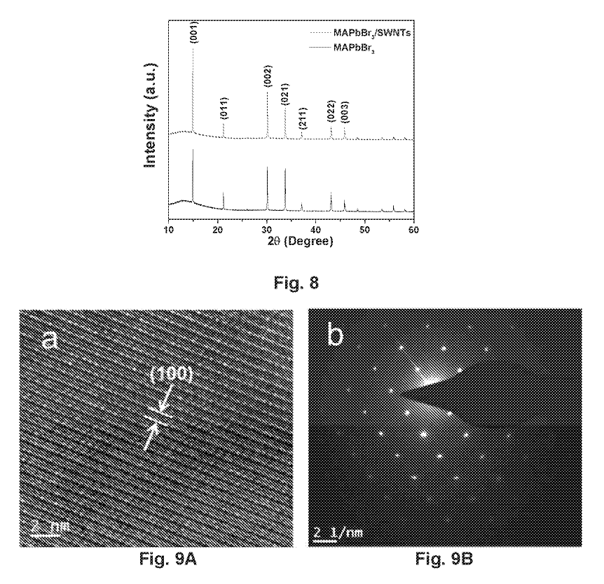

Satisfied that the inclusion of SWNTs into the perovskite matrix, we now turn to verify the crystalline nature of the composite. To do so, we have performed powder X-ray diffraction (XRD) measurements on perovskite SCs and perovskite/SWNT SCCs. FIG. 8 shows that the sharp peaks in both cases match well with the cubic MAPbBr₃ SCs XRD data¹³. The XRD data indicate that introducing SWNTs into the matrix did not change the cubic crystal structure of MAPbBr₃ SCs, and thus the optoelectronic and transport properties of the perovskite matrix may well be intact in the composite.

FIG. 1G shows the selected area electron diffraction (SAED) pattern of perovskite/SWNT composite. Comparing to that of pure perovskite (FIGS. 9A-B), the SAED of MAPbBr₃/SWNTs composite shows both regular spots and ring patterns, which were identified coming from perovskite and SWNTs, respectively.

### Optical and Transport Properties.

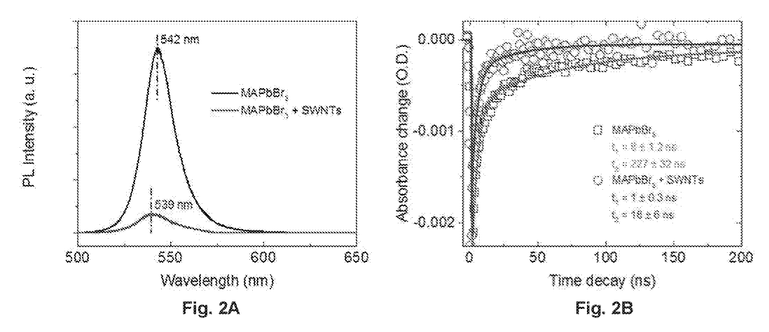

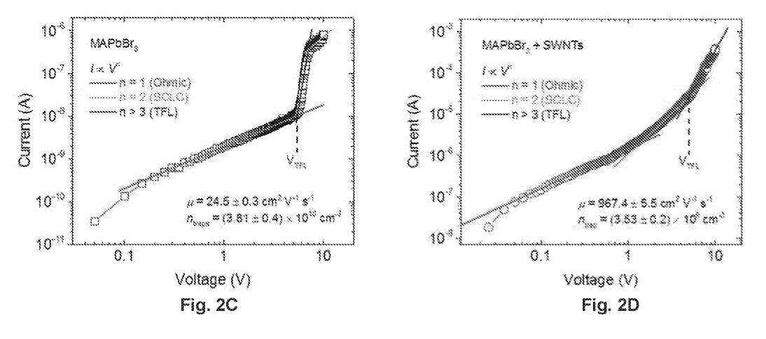

Steady-state photoluminescence (PL) measurements were performed to corroborate the scenario of charge transfer at the perovskite/SWNTs interface. The PL intensity of the SCC was quenched significantly compared to the SC, indicative of a charge transfer between MAPbBr₃ matrix and SWNTs inclusions. Moreover, The PL peak position was slightly blue shifted from 542 nm to 539 nm (see FIG. 2A), indicating that the interfacial structure changes slightly due to the addition of SWNTs. The PL peak position was shorter than the absorption cutoff in both the neat MAPbBr₃ SC and MAPbBr₃/SWNTs SCC. This unusual behavior was ascribed to the surface defects or to the decomposition-related product-induced trap state emission¹⁰.

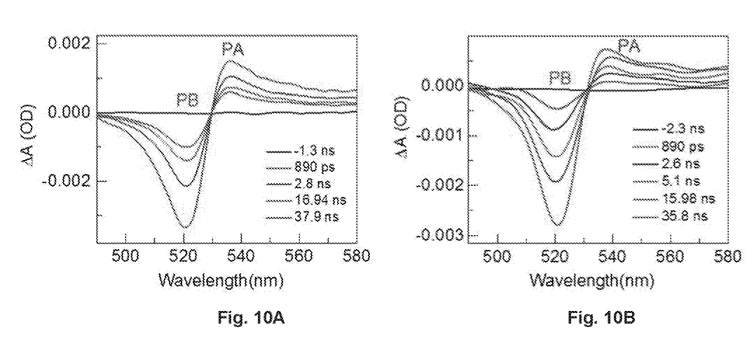

The charge generation and transfer between the perovskite and SWNTs are fundamental to explaining the optoelectronic properties of SCCs. We conducted transient absorption (TA) spectroscopy measurements to probe the lifetime of charge transfer between MAPbBr₃ and SWNTs. The TA spectra of MAPbBr₃ SC and MAPbBr₃/SWNTs SCC in FIGS. 10A-B shows a broad negative peak at 520 nm and a positive peak at 540 nm, which were assigned to the photo-bleaching (PB) and to photo-absorption (PA) of the band gap or exciton transition, respectively^{31, 32}. From the results obtained from dynamic spectra and biexponential data fitting, we retrieved the time constants for both materials. As shown in FIG. 2B, both of the time constants are apparently smaller in the case of SCCs than in MAPbBr₃ SCs, indicating that the charge extraction from the photoexcited MAPbBr₃ to SWNTs is much faster. Our results match well with those of Schulz et al.'s results that holes are extracted quickly by SWNTs and that the interfacial ground-state charge transfer reactions can establish beneficial interfacial band offsets and facilitate charge transfer and separation²³. Given that the carrier (hole) transfer mobility of SWNTs can go above 10,000 cm² V‘ s’,³³ we speculate that the ground state and/or the photo-generated hole transfer more quickly at the interface from perovskites to SWNTs and hinder recombination. We thus hypothesize the operational mechanism of the SCC to be as follows. First, the perovskite absorbs incident photons (the SWNTs also contribute as indicated by the UV-Vis spectra) and generate hole-electron pairs. Then, the holes are injected into the nearby SWNTs and transported through the SWNT network under the applied electric field, while electrons remain predominantly trapped at the surface of the SWNTs². These results confirm prior previous observations that SWNTs are efficient hole-transporting materials and can be suitable for perovskite solar cells.^{23, 34}

We studied the charge-transport properties of MAPbBr₃ SC and MAPbBr₃/SWNTs SCC in order to evaluate its potential for optoelectronic applications. We formed a capacitor-like device with selective hole injection by sandwiching the neat SC and SCC between two Au electrodes deposited by thermal evaporation, and investigated the evolution of space-charge-limited current (SCLC) under different biases (FIGS. 2C,D). For the neat SC, the I-V response was Ohmic at low voltages (i.e., linear), as confirmed by the fitting to an I-V functional dependence (magenta line). At intermediate voltages, the current exhibited a rapid nonlinear rise (set in at V_{TFL}=4.6 V) and signaled the transition onto the trap-filled limit (TFL)—a regime in which all the available trap states were filled by the injected carriers. Exploiting the linear dependence between V_{TFL} and the density of trap states nₜᵣₐₚₛ (FIG. 2C),

$${n}_{traps} = \frac{2 {ɛ}_{0} {ɛV}_{TFL}}{{eL}^{2}} \qquad ( 1 )$$

where L is the thickness of the crystal and e is the elementary charge, we estimated the trap density nₜᵣₐₚₛ to be ˜3.81×10¹⁰ cm⁻³. At high fields, the current showed a quadratic voltage dependence in the Child's regime. In this region, we extracted the value for the trap free mobility p by fitting with the Mott-Gumey law,

$${J}_{dark} = \frac{9 {ɛ}_{0} ɛμ {V}^{2}}{8 {L}^{3}} \qquad ( 2 )$$

where J_{dark} is the current density and V is the applied voltage. We found the carrier mobility p is about 24.5 cm² V⁻¹ s⁻¹ (FIG. 2C). The above obtained values are consistent with the previous reports^{13, 14}.

For the SCC, we determined the charge carrier mobility and trap density using the same methodology. Remarkably, we found that the I-V traces showed an Ohmic region at the lower electric field, then transited into a SCLC model at intermediate voltages, following the TFL regime at higher bias. We calculated the carrier mobility μ and trap density nₜᵣₐₚₛ to be 967.4 cm² V⁻¹ s⁻¹ and 3.53×10⁹ cm⁻³. The μ value obtained in the SCC is almost 40 fold higher than that of the neat SC and the trap density is an order of magnitude lower. It is therefore clear that high-mobility SWNTs networks embedded in the perovskite matrix provide fast tracks for carriers to be transported with less scattering, which benefits from the effective charge transfer from perovskites into SWNTs.

Fabrication and Characterization of Perovskite/SWNT SCC Photodetectors.

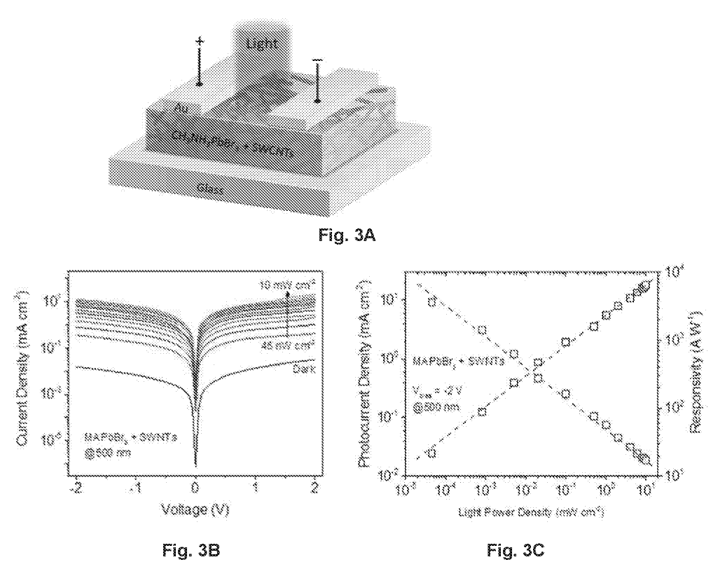

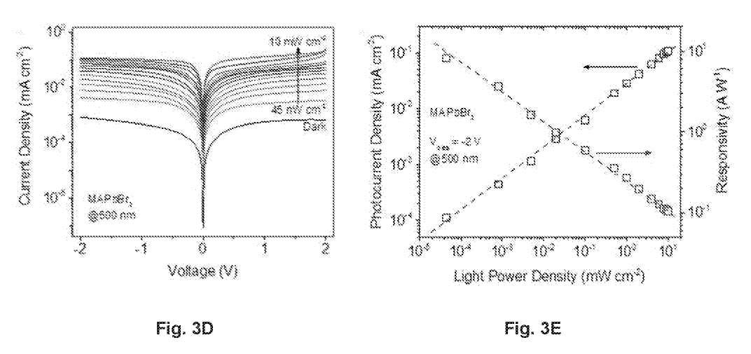

The photodetectors were fabricated using the as-grown neat SC and SCC as the active channel. The schematic illustration of the devices is presented in FIG. 3A. The Ti/Au (5 nm/80 nm) electrodes were deposited onto the surface of the crystals mounted on a glass substrate via thermal evaporation through a shadow mask, defining photodetector channels with a length of 20 μm and a width of 100 μm. For device characterization, a bias was applied between the two Au electrodes while monochromatic light illuminated the sample directly. All measurements were performed in air and at room temperature.

In FIGS. 3B and 3C, we plot the current density-voltage (J-V) characteristics of the SC and SCC photodetectors, measured in the dark and under light illumination with A=500 nm and different power densities under bias ranging between −2 and 2 V. The devices show symmetric J-V characteristics, indicating an ohmic contact with the two electrodes. The dark state current is on the order of dozens of microamps per square centimeter. Under laser light illumination (FIG. 3B), electron-hole pairs are generated and extracted by the electric field, causing an increase in the conductance of the material by a factor of 30. The J-V curves also show an obvious symmetrical behavior, indicating that a photoconductor is formed. The photocurrent density (black squares) of the SC and SCC devices increases dramatically with increasing laser power densities in the 45 nW cm² to 10 mW cm⁻² range. The channel current densities under light illumination (J_{light}) are two orders of magnitude higher in SCC devices (1.5×10¹ mA cm⁻² at 10 mW cm⁻²) as compared with SC devices (1.3×10⁻¹ mA cm⁻² at 10 mW cm⁻²). These results confirm our assumption that SWNT incorporation into perovskite SCs can significantly enhance the photo-induced charge carrier mobility, which effectively the photocurrent density of the hybrid devices. A very high photocurrent on the order of milliamps scale is observed, even in low illumination power densities, indicating that the embedding SWNTs significantly enhance the photo-induced charge carrier mobility and thus the conductivity of the SCC devices.

The photoresponsivity (R), indicating how efficiently the optoelectronic device responds to an optical signal, is an important figure-of-merit for evaluating the performance of phototransistors. It is given by⁹

$$R = \frac{{J}_{light} - {J}_{dark}}{{L}_{light}} , \qquad ( 3 )$$

where J_{dark} is the channel current density in the dark. The R (blue square) as a function of the illumination power is plotted in FIGS. 3D and 3E, for the SC and SCC devices, respectively. The maximum R of the SC-based photodetector was a respectable 8.4 A W⁻¹ at an optical power of 45 nW cm-2, while the SCC photodetector yielded an R of 3.9×10³ A W⁻¹ for the same optical power, a greater than two orders of magnitude improvement. This R value achieved with the SCC is substantially higher than most other photodetector materials^{8, 15, 35-39}, making it quite remarkable. For example, photodetectors based on organic semiconductors were reported with R values typically below 1.0 A W⁻¹.³⁹ The much-enhanced R of our SCC photodetector indicates a great deal of synergy between the perovskite matrix and the SWNT inclusions in the operational performance of the photodetector. Furthermore, we observed an increase of the R with decreasing incident light power in the case of SCC devices, eventually reaching saturation at low light intensity, a behaviour that is typical of photoconductive detectors. At higher illumination intensities, the increased number of separated charge carriers induced a reverse electric field, effectively lowering the built-in field. Charge carrier recombination is therefore accelerated at the interface with the consequence of a drop in R⁴⁰. In addition to this, saturation of sensitizing traps in the perovskite from photogenerated carriers may also contribute to the decrease in R³⁵. Further optimization of the SCC fabrication and device engineering may lead to further improvements of the performances of these photodetectors. Nevertheless, the SCC device operated much better than the SC device, in which R decreased as the irradiance increased, whereby the highest values for R could be measured at the lowest detectable irradiance power.

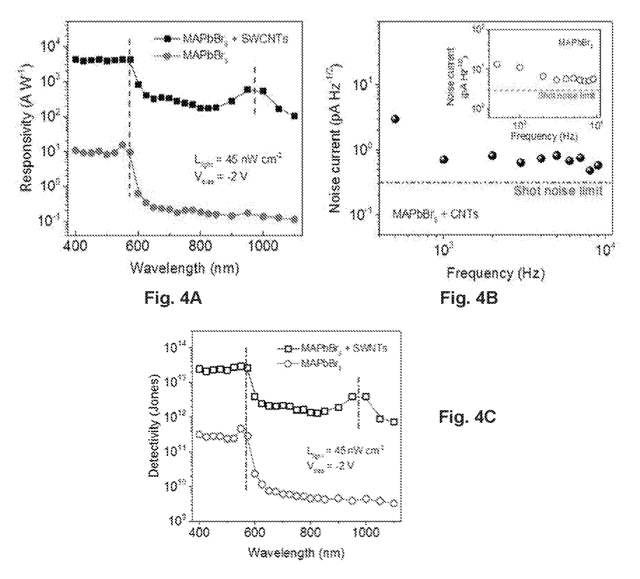

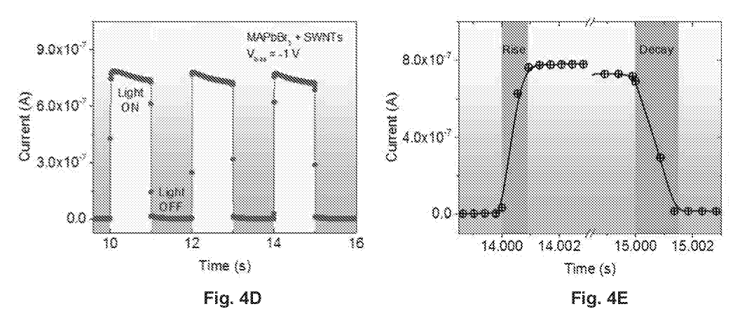

We further investigated the spectral responsivity of the SC and SCC photodetectors, as shown in FIG. 4A. The spectral sensitivity of the SC photodetector is determined by the bandgap of MAPbBr₃ SC of around 2.25 eV. The spectral sensitivity of the SCC is increased by more than two orders of magnitude as well as extended to NIR range thanks to the low bandgap of SWNTs⁴¹. The R in the NIR is impressive, reaching 614 A W⁻¹ at 975 nm for an incident light intensity of 45 nA cm⁻². The specific detectivity D* (measured in units of Jones, Jones=cm Hz^{1/2} W⁻¹) is another critical parameter for evaluating the performance of photodetectors. It is a measure of the capability of the devices to detect the incident light signal. The noise current is the main factor to limit the specific detectivity of the photodetectors, and the total noise current of our devices was directly measured with a lock-in amplifier at various frequencies. As shown in FIG. 4B, the measured noise currents of both photodetectors are dominated by the shot noise, and accordingly, the specific detectivity of the photodetectors is given by⁸

$${D}^{*} = \frac{{( Af )}^{1 / 2}}{( {i}_{n} / R )} \qquad ( 4 )$$

where A, f and in are the effective area of the devices, the electrical bandwidth and the noise current, respectively. In our case, the dark currents are dominated by the shot noise, so the detectivity can be simplified as

$${D}^{*} = \frac{R}{{( 2 {qJ}_{dark} )}^{1 / 2}} \qquad ( 5 )$$

where q is the absolute value of electron charge (1.602×10⁻¹⁹ Coulombs). The detectivities of the SC and SCC photodetectors is plotted as a function of wavelength in FIG. 4C. At an illumination intensity of 45 nW cm⁻² at 550 nm, the maximum D* of 4.9×10¹ Jones was obtained for the SC device, while the SCC device yielded nearly two orders of magnitude greater D* of 3.8×10¹³ Jones. We note here that the obtained D* values for the SCC device is comparable to the highest values ever reported for either organic or inorganic materials³⁷⁻³⁹. Remarkably, the SCC photodetector also shows a high detectivity of 5.2×10¹² Jones in the NIR region (975 nm), which is consistent with its spectral responsivity property. The remarkably high D* of the SCC photodetector both in the visible and NIR regions at room temperature, in combination with the simple device architecture, should enable the detection of very weak light signal and enable its implementation in high-sensitivity photodetector applications. The remarkable figures of merit (R and D*), especially in the NIR, were made possible by combining the remarkable properties of perovskites with those of SWNTs, which interact favorably, enabling charge transport in the SWNTs and enhancing the NIR light absorption, significantly improving the overall performance.

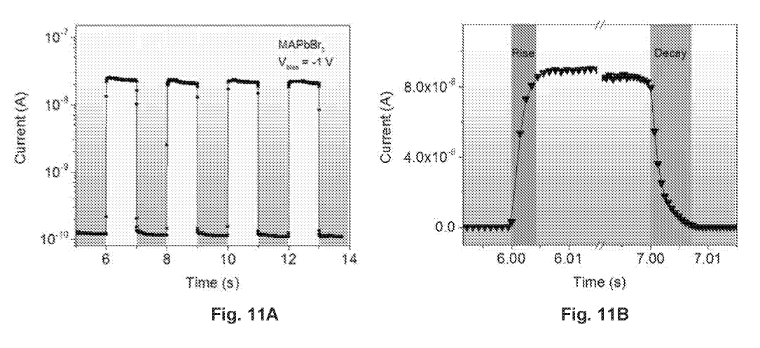

Another important parameter of optoelectronic devices is their response speed. The temporal response of our hybrid photodetector was characterized using chopper-generated light pulses. The optical pulses had the time interval of 1.0 s, and the device was measured under the bias voltage of V w, =−1 V and A=500 nm. As shown in FIG. 4D, the dynamic photoresponse of the hybrid photodetector is stable and reproducible, indicating that the device can function as a good light switch. The temporal photocurrent response of the hybrid photodetector is presented in FIG. 4E. The switching times for the rise (output signal changing from 0 to 90% of the peak output value) and the decay (I_{DS} decreasing from peak value to 10%) of the photocurrent are about 0.91 ms and 1.43 ms, respectively, which can also be taken as the carrier lifetime τ_{life}. In contrast, the on/off switching of the SC photoconductor is approximately four orders of magnitude slower than the SCC device (FIGS. 11A-B). It is noted that the response speed of our hybrid photodetector is faster than some organic, quantum dot and hybrid photodetectors^{35-37, 39, 42}, which arises from the good carrier transport in the SCC. The faster photoresponse of the SCC hybrid photodetector could be attributed to the efficient charge separation at the perovskite-SWNT interface.

The photoconductive gain (G) is the ratio between τ_{life} and the transit time (τₜᵣₐₙ, which is the time during which holes sweep through the SWNTs to the electrodes), and given by

$$G = \frac{{τ}_{life}}{{τ}_{tran}} = \frac{{τ}_{life}}{{d}^{2} / μ \cdot {V}_{bias}} \qquad ( 6 )$$

where d and μ are the channel length and the carrier mobility, respectively. Based on the measured carrier recombination time and the carrier mobility, the gain of our hybrid devices can be estimated to be ˜1.1×10⁵; while for the devices based on SC, the gain is less than half (4.6×10⁴). This further underscores the potential of SCCs as promising material candidates for photoelectronic applications.

### CONCLUSION

In this application, we demonstrate a remarkably successful integration of two unlikely materials, namely a semiconductor single crystal and carbon nanotubes into a macroscopic composite material. In doing so we have demonstrated the remarkable ability to solution-grow organohalide perovskite single crystals through and around a SWNT network, resulting in a single crystals-like composite. The energetically favorable interfacial electronic structures lead to charge transfer to the SWNTs capable of moving charges orders of magnitude faster than the perovskite matrix. The perovskite thus sensitizes the SWNT network while the latter extends the absorption of the CSC spectrum well into to the NIR. We demonstrate high-performance photodetectors using the CSC with a broad spectral response from 400 nm to 1100 nm, with responsivities over 3895 A W⁻¹ and 614 A W⁻¹, detectivities higher than 3.8×10¹³ Jones and 5.2×10¹² Jones in the visible and NIR regions, respectively. The SCC shows a high gain of about 1.1×10⁵ electrons per photon and the carrier mobility goes up to 967 cm² V⁻¹s⁻¹. These device performance metrics are state of the art and compare favorably to the best organic and inorganic materials used in photodetectors. Based on this novel composite semiconductor approach, it is expected that more efficient optoelectronic devices, such as light emitting devices and phototransistors may emerge.

### Methods

### Materials.

CH₃NH₃Br (MABr) was purchased from Dyesol company. Lead bromide (PbBr₂) and single walled carbon nanotubes (SWNTs, (7.6) chirality, diameter 0.9±0.2 nm) were both commercials from Sigma-Aldrich.

### SCs Preparation and Device Fabrication.

The SWNTs were first processed in 3M HNO₃ before cleaning with lots of DI water, centrifugation and finally freeze-drying. 0.2 M MABr and PbBr₂ in N, N-dimethylformamide (DMF) was prepared for pure MAPbBr₃.

SCs and SWNTs were introduced into the solution with the weight ratio of 0.2 mg/ml for MAPbBr₃/SWNTs SCC. Dichloromethane (DCM) was used as anti-solvent to help SCs growth. Ti/Au electrodes (5 nm/80 nm) were deposited via thermal evaporation through a shadow mask, defining device channels with length of 20 μm and width of 100 μm.

### Device Characterizations.

UV-Vis spectra were collected using a Cary 5000 (Varian) spectrophotometer equipped with an integrating sphere. Photoluminescence measurement was conducted on a DXR smart raman spectrometer with the excitation laser 473 nm. Powder X-ray diffraction (XRD) was performed at room temperature using an X-ray diffractometer (D8 Discover, Bruker). Optical microscope was acquired from Nikon's SMZ25 stereomicroscope. The surface morphology of the films was measured using SEM (FEI Nova Nano 630). Transmission electron microscopy (TEM) images and selected area electron diffraction (SAED) images were captured using a TITAN ST operated at 180 kV. For the nanosecond transient absorption spectroscopy, a few μJ of pulse energy as the fundamental output from a Ti:Sapphire nanosecond regenerative amplifier (800 nm, 35 fs fwhm, 1 kHz) was used to generate pump and probe beams. By introducing the fundamental beams into an optical parametric amplifier (Newport Spectra-Physics), we could select a certain wavelength from the tunable output (240-2600 nm) as the pump pulses, whereas light continuum probe pulses were obtained by focusing the fundamental beams onto a 2-mm thick sapphire plate (contained in an Ultrafast System LLC spectrometer). The pump and probe pulses overlapped by a small angle of less than 5° on the perovskite samples. I-V measurements were conducted using a Signotone Micromanipulator S-1160 probe station equipped with a LED and Keithley 4200 SCS. Noise current was measured with a lock-in amplifier SR830. SCLC measurement was performed by evaporating gold (100 nm) on both sides of the sample. For SCLC measurements, I-V curves were carried out under vacuum (˜10⁻¹ mbar), in the dark, and at 300 K, in the simple two electrode configuration (Au/MAPbBr₃/Au). The perovskite crystal was sandwiched between the rectangular electrodes Au (100-nm thickness), deposited on both sides of the single crystal, by a thermal evaporator. The thickness of MAPbBr₃ crystals and MAPbBr₃/SWNTs composite crystal were measured via using the digital Vernier caliper. A non-linear response was observed and analyzed according to SCLC theory.

### REFERENCES FOR EXAMPLE 1

1. Kojima, A., Teshima, K., Shirai, Y. & Miyasaka, T. Organometal Halide Perovskites as Visible-Light Sensitizers for Photovoltaic Cells. Journal of the American Chemical Society 131, 6050-6051 (2009).
2. Lee, M. M., Teuscher, J., Miyasaka, T., Murakami, T. N. & Snaith, H. J. Efficient Hybrid Solar Cells Based on Meso-Superstructured Organometal Halide Perovskites. Science 338, 643-647 (2012).
3. Yang, W. S. et al. High-performance photovoltaic perovskite layers fabricated through intramolecular exchange. Science 348, 1234-1237 (2015).
4. Jeon, N. J. et al. Compositional engineering of perovskite materials for high-performance solar cells. Nature 517, 476-480 (2015).
5. Tan. Z.-K. et al. Bright light-emitting diodes based on organometal halide perovskite. Nature Nanotechnology 9, 687-692 (2014).
6. Cho, H. et al. Overcoming the electroluminescence efficiency limitations of perovskite light-emitting diodes. Science 350, 1222-1225 (2015).
7. Gong, X. et al. Highly efficient quantum dot near-infrared light-emitting diodes. Nat Photon 10, 253-257 (2016).
8. Hu, X. et al. High-Performance Flexible Broadband Photodetector Based on Organolead Halide Perovskite. Advanced Functional Materials 24, 7373-7380 (2014).
9. Dou, L. et al. Solution-processed hybrid perovskite photodetectors with high detectivity. Nat Commun 5, 5404 (2014).
10. Fang, Y., Dong, Q., Shao, Y., Yuan, Y. & Huang, J. Highly narrowband perovskite single-crystal photodetectors enabled by surface-charge recombination. Nat Photon 9, 679-686 (2015).
11. Lin, Q., Armin, A., Burn, P. L. & Meredith. P. Filterless narrowband visible photodetectors. Nature Photonics 9, 687-694 (2015).
12. Li, F. et al. Ambipolar solution-processed hybrid perovskite phototransistors. Nat Commun 6, 8238 (2015).
13. Shi, D. et al. Low trap-state density and long carrier diffusion in organolead trihalide perovskite single crystals. Science 347, 519-522 (2015).
14. Dong, Q. Electron-hole diffusion lengths >175 μm in solution-grown CH3NH3PbI3 single crystals. Science 347, 967-970 (2015).
15. Maculan, G. et al. CH3NH3PbCl3 Single Crystals: Inverse Temperature Crystallization and Visible-Blind UV-Photodetector. Journal of Physical Chemistry Letters 6, 3781-3786 (2015).
16. Green, M A., Ho-Baillie, A. & Snaith, H. J. The emergence of perovskite solar cells. Nature Photonics 8, 506-514 (2014).
17. Peng, W. et al. Solution-Grown Monocrystalline Hybrid Perovskite Films for Hole-Transporter-Free Solar Cells. Advanced Materials, 3383-3390 (2016).
18. de Quilettes, D. W. et al. Impact of microstructure on local carrier lifetime in perovskite solar cells. Science 348, 683-686 (2015).
19. Dou, L. et al. Atomically thin two-dimensional organic-inorganic hybrid perovskites. Science 349, 1518-1521 (2015).
20. Wang, G. et al. Wafer-scale growth of large arrays of perovskite microplate crystals for functional electronics and optoelectronics. Science Advances 1, e150061 (2015).
21. Yang, Y. et al. Low surface recombination velocity in solution-grown CH3NH3PbBr3 perovskite single crystal. Nature Communications 6, 7961 (2015).
22. Jeon, I. et al. Single-Walled Carbon Nanotube Film as Electrode in Indium-Free Planar Heterojunction Perovskite Solar Cells: Investigation of Electron-Blocking Layers and Dopants. Nano Letters 15, 6665-6671 (2015).
23. Schulz, P. et al. Charge Transfer Dynamics between Carbon Nanotubes and Hybrid Organic Metal Halide Perovskite Films. The Journal of Physical Chemistry Letters, 418-425 (2016).
24. H. Sargent, E. Infrared Quantum Dots. Advanced Materials 17, 515-522 (2005).
25. Ettenberg, M. A Little Night Vision. Advanced Imaging 20, 29-32 (2005).
26. Sargent, E. H. Infrared photovoltaics made by solution processing. Nat Photon 3, 325-331 (2009).
27. Vekilov, P. G. Nucleation. Crystal Growth & Design 10, 5007-5019 (2010).
28. Vekilov, P. G. What Determines the Rate of Growth of Crystals from Solution? Crystal Growth & Design 7, 2796-2810 (2007).
29. Hodge, S. A., Bayazit, M. K., Coleman, K. S. & Shaffer, M. S. P. Unweaving the rainbow: a review of the relationship between single-walled carbon nanotube molecular structures and their chemical reactivity. Chemical Society Reviews 41, 4409-4429 (2012).
30. Hennrich, F. et al. Raman Spectroscopy of Individual Single-Walled Carbon Nanotubes from Various Sources. The Journal of Physical Chemistry B 109, 10567-10573 (2005).
31. Stranks, S. D. et al. Electron-Hole Diffusion Lengths Exceeding 1 Micrometer in an Organometal Trihalide Perovskite Absorber. Science 342, 341-344 (2013).
32. Xing, G. et al. Long-Range Balanced Electron- and Hole-Transport Lengths in Organic-Inorganic CH3NH3PbI3. Science 342, 344-347 (2013).
33. Darkop, T., Getty, S. A., Cobas, E. & Fuhrer, M. S. Extraordinary Mobility in Semiconducting Carbon Nanotubes. Nano Letters 4, 35-39 (2004).
34. Qiu, L., Deng, J., Lu, X., Yang, Z. & Peng, H. Integrating Perovskite Solar Cells into a Flexible Fiber. Angewandte Chemie—International Edition 53, 10425-10428 (2014).
35. Konstantatos, G. et al. Hybrid graphene-quantum dot phototransistors with ultrahigh gain. Nature Nanotechnology 7, 363-368 (2012).
36. Konstantatos, G. et al. Ultrasensitive solution-cast quantum dot photodetectors. Nature 442, 180-183 (2006).
37. Koppens, F. H. L. et al. Photodetectors based on graphene, other two-dimensional materials and hybrid systems. Nat Nano 9, 780-793 (2014).
38. Lee, Y. et al. High-Performance Perovskite-Graphene Hybrid Photodetector. Advanced Materials 27, 41-46 (2015).
39. Baeg, K.-J., Binda, M., Natali, D., Caironi, M. & Noh, Y.-Y. Organic Light Detectors: Photodiodes and Phototransistors. Advanced Materials 25, 4267-4295 (2013).
40. Kufer, D. et al. Hybrid 2D-0D MoS2-PbS Quantum Dot Photodetectors. Advanced Materials 27, 176-180 (2015).
41. Avouris, P., Freitag, M. & Perebeinos, V. Carbon-nanotube photonics and optoelectronics. Nature Photonics 2, 341-350 (2008).
42. Roy, K. et al. Graphene-MoS2 hybrid structures for multifunctional photoresponsive memory devices. Nat Nano 8, 826-830 (2013).

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. In an embodiment. “about 0” can refer to 0, 0.001, 0.01, or 0.1. In an embodiment, the term “about” can include traditional rounding according to significant figures of the numerical value. In addition, the phrase “about ‘x’ to ‘y’” includes “about ‘x’ to about ‘y’”.

It should be emphasized that the above-described embodiments of the present disclosure are merely possible examples of implementations, and are set forth only for a clear understanding of the principles of the disclosure. Many variations and modifications may be made to the above-described embodiments of the disclosure without departing substantially from the spirit and principles of the disclosure. All such modifications and variations are intended to be included herein within the scope of this disclosure.

1. A material, comprising: a composite of halide perovskite single crystals and nanotubes, wherein a type I heterojunction is formed between halide perovskite single crystal and nanotubes.

2. The material of claim 1, wherein the halide perovskite is AMX3, wherein A is an organic cation, M is a divalent cation selected from the group consisting of: Pb, Sn, Cu, Ni, Co, Fe, Mn, Pd, Cd, Ge, Cs, and Eu, and X is selected from a halide.

3. The material of claim 1, wherein the halide perovskite is selected from the group consisting of: MAPbBr₃, MAPbI₃, FAPbBr₃, FAPbI₃, MAPbCl₃, MAPbBr₂Cl, FAPbCl₃, CsPbI₃, CsPbCl₃, CsPbBr₃, FASnBr₃, FASnI₃, FASnCl₃, MASnI₃, and MASnCl₃, wherein MA is methylammonium and FA is formamidinum.

4. The material of claim 1, wherein the halide perovskite is MAPbBr₃.

5. The material of claim 1, wherein the nanotube is a carbon nanotube.

6. The material of claim 5, wherein the carbon nanotube is a single walled carbon nanotube.

7. The material of claim 1, wherein the halide perovskite single crystals are in a matrix, and wherein the single walled carbon nanotubes are embedded in the matrix.

8. The material of claim 1, wherein the ratio of the halide perovskite single crystal to nanotube is about 1000:1 to 10:1.

9. A photodetector device comprising: a composite of halide perovskite single crystals and nanotubes, wherein a type I heterojunction is formed between halide perovskite single crystal and nanotubes.

10. The photodetector device of claim 9, wherein the halide perovskite is AMX3, wherein A is an organic cation, M is a divalent cation selected from the group consisting of: Pb, Sn, Cu, Ni, Co, Fe, Mn, Pd, Cd, Ge, Cs, and Eu, and X is selected from a halide.

11. The photodetector device of claim 9, wherein the halide perovskite is selected from the group consisting of: MAPbBr₃, MAPbI₃, FAPbBr₃, FAPbI₃, MAPbCl₃, MAPbBr₂Cl, FAPbCl₃, CsPbI₃, CsPbCl₃, CsPbBr₃, FASnBr₃, FASnI₃, FASnCl₃, MASnBr₃, MASnI₃, and MASnCl₃, wherein MA is methylammonium and FA is formamidinum.

12. (canceled)

13. The photodetector device of claim 9, wherein the nanotube is a carbon nanotube.

14. The photodetector device of claim 13, wherein the carbon nanotube is a single walled carbon nanotube.

15. The photodetector device of claim 9, wherein the halide perovskite single crystals are in a matrix, and wherein the single walled carbon nanotubes are embedded in the matrix.

16. (canceled)

17. A solar cell, comprising: a composite of halide perovskite single crystals and nanotubes, wherein a type I heterojunction is formed between halide perovskite single crystal and nanotubes.

18. The solar cell of claim 17, wherein the halide perovskite is AMX3, wherein A is an organic cation, M is a divalent cation selected from the group consisting of: Pb, Sn, Cu, Ni, Co, Fe, Mn, Pd, Cd, Ge, Cs, and Eu, and X is selected from a halide.

19. The solar cell of claim 17, wherein the halide perovskite is selected from the group consisting of: MAPbBr₃, MAPbI₃, FAPbBr₃, FAPbI₃, MAPbCl₃, MAPbBr₂Cl, FAPbCl₃, CsPbI₃, CsPbCl₃, CsPbBr₃, FASnBr₃, FASnI₃, FASnCl₃, MASnBr₃, MASnI₃, and MASnCl₃, wherein MA is methylammonium and FA is formamidinum.

20. (canceled)

21. The solar cell of claim 17, wherein the nanotube is a carbon nanotube.

22. The solar cell of claim 21, wherein the carbon nanotube is a single walled carbon nanotube.

23. The solar cell of claim 17, wherein the halide perovskite single crystals are in a matrix, and wherein the single walled carbon nanotubes are embedded in the matrix.

24. (canceled)
